(19) United States
(12) Patent Application Publication
(10) Pub. No.: US 2026/0136983 A1
(43) Pub. Date: May 14, 2026

(54) MULTIPLE EPOXY COMPOUNDS FOR MEMORY SYSTEM MANUFACTURING

(71) Applicant: Micron Technology, Inc., Boise, ID (US)

(72) Inventors: Kimball D. Lowry, Boise, ID (US); Bradley Bitz, Meridian, ID (US)

(21) Appl. No.: 19/380,740

(22) Filed: Nov. 5, 2025

Related U.S. Application Data
(60) Provisional application No. 63/719,013, filed on Nov. 11, 2024.

(51) Int. Cl. H01L 21/56; H01L 21/67; H01L 23/29; H01L 23/373

(52) U.S. Cl. CPC H10W 74/016; H10P 72/0441; H10W 40/251; H10W 74/014; H10W 74/473

(57) ABSTRACT

Methods, systems, and devices for multiple epoxy compounds for memory system manufacturing are described. The method may include forming a substrate and semiconductor packages on the substrate. Further, the method may include inserting a first epoxy compound in a first region of a cavity between the substrate and a molding tool and inserting a second epoxy compound in a second region of the cavity. In some examples, a thermal or an electrical property of the first epoxy compound may be different than a thermal or an electrical property of the second epoxy compound. Additionally, the method may include moving the device or the molding tool towards one another to form an insulating layer that at least partially surrounds the semiconductor packages and includes the first epoxy compound and the second epoxy compound.

### CROSS REFERENCE

The present Application for Patent claims priority to U.S. patent application No. 63/719,013 by Lowry et al., entitled “MULTIPLE EPOXY COMPOUNDS FOR MEMORY SYSTEM MANUFACTURING,” filed Nov. 11, 2024, which is assigned to the assignee hereof, and which is expressly incorporated by reference in its entirety herein.

### TECHNICAL FIELD

The following relates to one or more systems for memory, including multiple epoxy compounds for memory system manufacturing.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

In some examples, a manufacturing system may perform compression molding during semiconductor packaging to form an insulating layer that surrounds one or more stacks of memory dies of a memory system. To perform compression molding, the manufacturing system may dispense granular epoxy mold compound (EMC) to fill a mold cavity and subsequently compress the EMC to form the insulating layer.

### BRIEF DESCRIPTION OF THE DRAWINGS

FIG. 1 shows an example of a system that supports multiple epoxy compounds for memory system manufacturing in accordance with examples as disclosed herein.

FIG. 2 shows an example of a system that supports multiple epoxy compounds for memory system manufacturing in accordance with examples as disclosed herein.

FIGS. 3A, 3B, and 3C shows an example of a system that supports multiple epoxy compounds for memory system manufacturing in accordance with examples as disclosed herein.

FIG. 4 shows a block diagram of a manufacturing system that supports multiple epoxy compounds for memory system manufacturing in accordance with examples as disclosed herein.

FIG. 5 shows a flowchart illustrating a method or methods that support multiple epoxy compounds for memory system manufacturing in accordance with examples as disclosed herein.

### DETAILED DESCRIPTION

A system (e.g., a manufacturing system) may perform operations to form one or more components of a memory system. For example, the system may perform compression molding to form an insulating layer that partially surrounds one or more stacks of memory die of the memory system. As a part of compression molding, the system may deposit a single epoxy compound (e.g., an epoxy mold compound (EMC)) in a cavity between a substrate and a molding tool and compress the epoxy compound by moving one or both of the molding tool or the substrate towards one another to form the insulating layer. However, the single epoxy compound may not be suitable for all areas of the insulating layer.

As described herein, the insulating layer of the memory system may be formed using multiple epoxy compounds and a location of an epoxy compound within the insulating layer may be based on one or more properties of the epoxy compound such that a performance of the memory system is improved. In some examples, the system may position a molding tool over a device that includes the substrate and the one or more memory die stacks. The one or more memory die stacks may be positioned on the substrate such that the one or more memory die stacks are between the molding tool and the substrate. In some examples, the molding tool may not be in contact with the substrate resulting in a cavity of empty space between the substrate and the molding tool.

As part of compression molding, the system may deposit, in the cavity, multiple epoxy compounds that each differ in at least one electrical or thermal property. For example, the system may deposit a first epoxy compound in a first region of the cavity and a second epoxy compound in a second region of the cavity. Upon depositing the multiple epoxy compounds in the cavity, the system may compress the multiple epoxy compounds by moving one or both of the substrate or the molding tool towards one another to form an insulating layer that at least partially surrounds the one or more stacks of memory die and includes the multiple epoxy compounds.

In some examples, the system may strategically deposit the multiple epoxy compounds (e.g., epoxy components) in the cavity to optimize performance of the memory system. For example, the first epoxy compound may have better heat dissipation capabilities than the second epoxy compound. As such, the system may deposit the first epoxy compound in the first region of the cavity such that, after compression, a first portion of the insulating layer adjacent to sensitive components of the memory system include the first epoxy compound. That way, the first epoxy compound may pull heat away from the sensitive components. Using the methods as described herein may increase memory system performance.

In addition to applicability in memory systems as described herein, techniques for multiple epoxy mold compounds for memory system manufacturing may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving a performance of an electronic device (e.g., by forming an insulating layer using multiple epoxy mold compounds that are selectively deposited based on a specific need of the insulating layer), which may extend the life of electronic devices and thereby reducing electronic waste, among other benefits.

Features of the disclosure are illustrated and described in the context of systems and architectures. Features of the disclosure are further illustrated and described in the context of flowcharts.

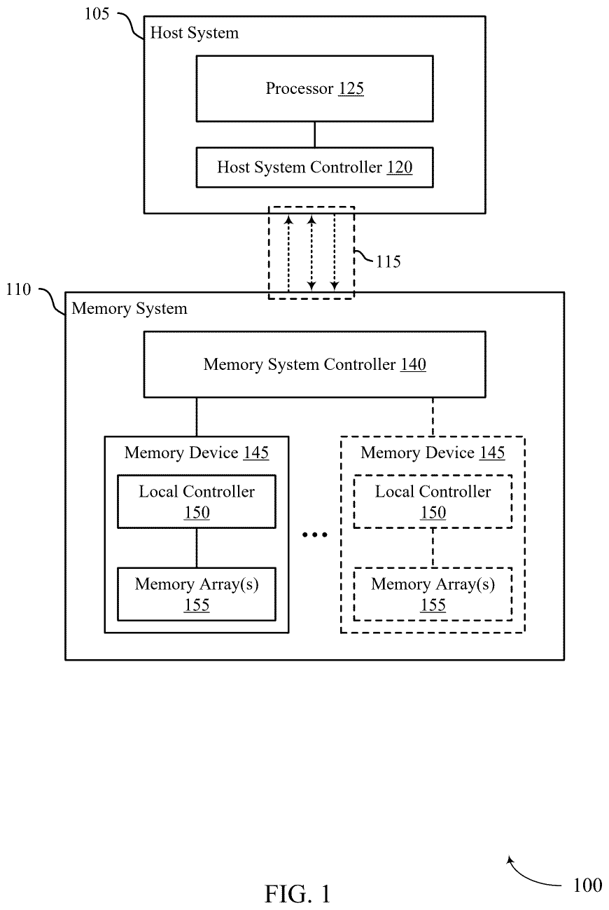

FIG. 1 illustrates an example of a system 100 that supports multiple epoxy compounds for memory system manufacturing in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Although shown and described with reference to a 2:1 memory system configuration where two memory dies (e.g., memory devices 145) are coupled with one logic die, the techniques described herein may be implemented in other memory system configurations, such as a 4:1 configuration, a 4:2 configuration, a 2:2 configuration, a 8:1 configuration, a 12:1 configuration, a 16:1 configuration and so on, where an n:N configuration refers to a configuration with n memory dies and N logic dies. In some examples (e.g., in coupled DRAM stacked memory systems) there may be multiple (e.g., 4, 6, 8) n:N configuration stacks (e.g., 8:1 configuration, 12:1 configuration, 16:1 configuration) on a processor (e.g., a CPU, a GPU)

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

As described herein, an apparatus (e.g., the memory system 110) may include an insulating layer that includes two or more epoxy compounds. A method for manufacturing the apparatus may include forming a substrate (e.g., a wafer or a panel) and semiconductor packages (e.g., one or more memory devices 145) on the substrate. Further, the method may include forming a first epoxy compound in a first region of a cavity between the substrate and a molding tool and forming a second epoxy compound in a second region of the cavity. In some examples, a thermal or an electrical property of the first epoxy compound may be different than a thermal or an electrical property of the second epoxy compound. A

Additionally, the method may include moving the device or the molding tool towards one another to form an insulating layer that at least partially surrounds the semiconductor packages. As a result, different portions of the insulating layer may include different epoxy compounds. For example, a first portion of the insulating layer may include the first epoxy mold compound and a second portion of the insulating layer may include the second epoxy mold compound. Each epoxy compound may be strategically placed in different portions of the insulating layer to address performance concerns relative to the portion thereby optimizing the performance of the apparatus.

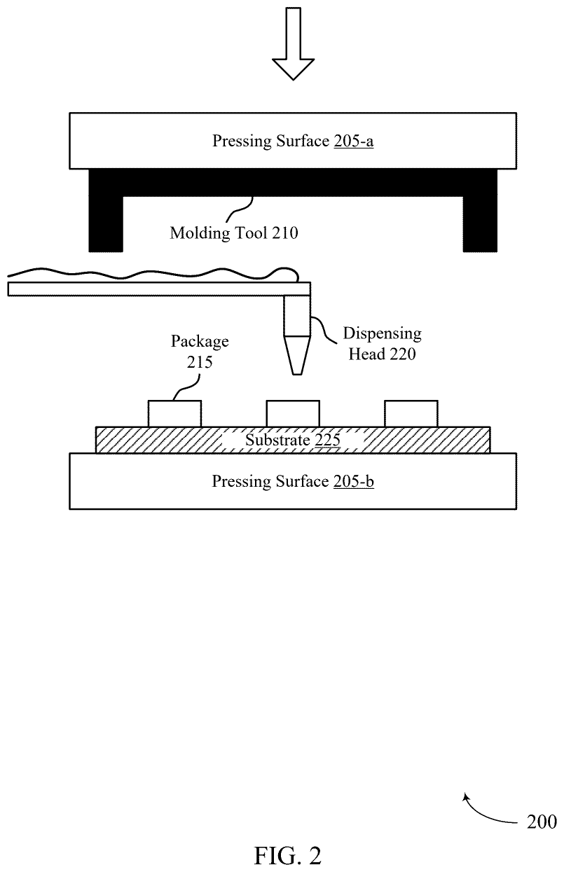

FIG. 2 shows an example of a system 200 that supports multiple epoxy compounds for memory system manufacturing in accordance with examples as disclosed herein.

A manufacturing process may implement the system 200 to form one or more components of a memory system (e.g., the memory system 110). In some examples, the system 200 may perform compression molding to form an insulating layer that surrounds one or more memory packages 215 (e.g., one or more stacks of memory dies) of the memory system. In some implementations, each stack of memory dies includes at least 4, 8, 12, or 16 dies. As shown in FIG. 2, the system 200 may include one or more of a pressing surface 205-a, a pressing surface 205-b, a molding tool 210, or a dispensing head 220.

Compression bonding may include one or more operations. Compression bonding in semiconductor manufacturing is a process that may be used to join two surfaces or layers together under heat and pressure. In some examples of compression bonding, at least two semiconductor materials are brought into contact under controlled conditions of temperature and pressure. The heat causes the materials to become slightly malleable, and the pressure forces them together. The atoms at the surface of each material interact and form bonds that may in essence wield the materials together. In some cases, this process may be a way to avoid using additional adhesive or soldering material, which can introduce impurities or defects into the semiconductor device. As part of a first operation, a substrate 225 of the memory system may be placed on a pressing surface 205-a of the system 200 such that the substrate 225 is positioned between the pressing surface 205-a and the pressing surface 205-b of the system 200. In some examples, one or more memory packages 215 may be coupled with the substrate 225 (e.g., coupled with a top surface of the substrate 225) such that the memory packages 215 are positioned between the substrate 225 and the pressing surface 205-a.

As part of a second operation, the system 200 may dispense (e.g., insert) two or more EMCs in a cavity of the system 200 (e.g., an empty space between the molding tool 210 and the substrate 225). In one example, dispensing the two or more EMCs may include dispensing the two or more EMCs on (or over) the substrate 225. In another example, dispensing the two or more EMCs may include dispensing the two or more EMCs on (or over) the molding tool 210. In such examples, the molding tool 210 and the substrate 225 may switch positions with respect to FIG. 2.

In some examples, the system 200 may use one or more dispensing heads 220 to deposit the two or more EMCs in the cavity. As one example, the system 200 may include a single dispensing head 220. In such examples, when switching from one EMC to another EMC, the system 200 may replace a material supplied to the single dispensing head 220. Alternatively, the system 200 may include multiple dispensing heads 220 that each deposit a different EMC of the two or more EMCs.

An EMC may be described as a composite material mainly composed of epoxy resin and filler. In some examples, an EMC may be a type of encapsulation material used in the manufacturing of semiconductor devices. An EMC may be designed to protect components of the semiconductor device (e.g., semiconductor chip) from environmental factors such as moisture, dust, and mechanical stress, while also providing electrical insulation. An EMC may be made from a combination of epoxy resin, hardeners, fillers, and/or other additives. Not all EMCs are identical and may vary from one another in epoxy type, filler composition, size, or density. Further, different EMCs may exhibit different properties due to these variations. The specific formulation can be adjusted to meet the requirements of different applications. For example, different EMC may exhibit different thermal properties (thermal expansion, heat capacity, thermal conductivity, or thermal stress), electrical properties (e.g., conductance, resistance, resistivity, or dielectric strength), mechanical properties (e.g., brittleness, strength, toughness, lower stress on protected components), etc. In some encapsulation processes, a semiconductor component is placed in a mold, and the EMC is injected into the mold, surrounding the component. The EMC may be cured, or hardened, to form a solid protective shell around the component, in some cases.

In some examples, the system 200 may dispense different EMCs in different regions of the cavity such that performance of the memory system is optimized. For example, the system 200 may dispense at least a first EMC in a first region of the cavity and a second EMC in second region of the cavity different from the first region. In some examples, the system 200 may be programmed with a pattern that indicates which EMC to dispense in which region of the cavity and the one or more dispensing heads 220 may dispense the two or more EMCs according to the pattern.

As part of a third operation, the system 200 may move one or both of the pressing surface 205-a or the pressing surface 205-b such that a vertical distance between the pressing surface 205-a and the pressing surface 205-b is decreased. In some examples, the system 200 may move one or both of the pressing surface 205-a or the pressing surface 205-b until the molding tool 210 is in contact with the substrate 225. In some examples, moving one or both of the pressing surface 205-a or the pressing surface 205-b may compress the two or more EMCs dispensed in the cavity forming a solid insulating layer that at least partially surrounds the memory packages 215.

Different regions of the insulating layer may include different EMCs. For example, a region of the insulating layer that is adjacent to or at least partially surrounds one or more external wires of a memory package 215 may include the first EMC and other regions of the insulating layer may include the second EMC. In such examples, the first EMC may have better electrical performance (e.g., a higher dielectric strength) than the second EMC to prevent cross-talk and improve shielding of the wires. Using the methods and apparatus as described herein, overall performance of the memory system may be improved. Further, because a less expensive EMC may be used in conjunction with more expensive EMC, a cost associated with manufacturing the memory system may be reduced when compared to solely using the more expensive EMC.

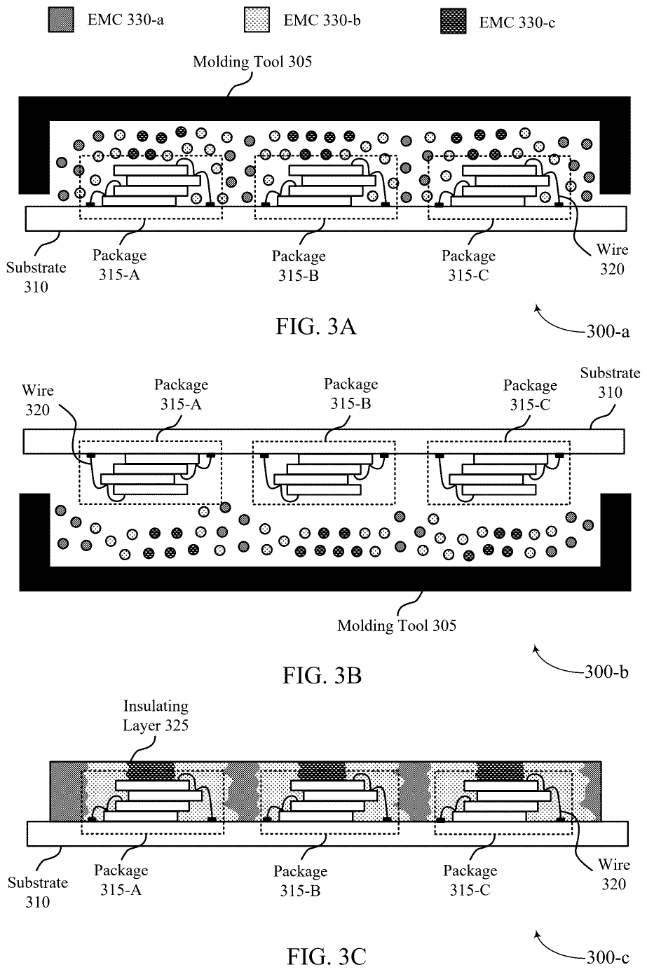

FIGS. 3A, 3B, and 3C show examples of a system 300 (e.g., a system 300-a, a system 300-b, and a system 300-c) that support multiple EMCs for memory system manufacturing in accordance with example as disclosed herein. In some examples, the systems 300 may implement aspects of the system 200. For example, the system 300-a and the system 300-b may include a molding tool 305 which may be an example of a molding tool 210 as described with reference to FIG. 2. Further, the systems 300 may include a substrate 310 and packages 315, which may be examples of the substrate 225 and the memory packages 215 as described with reference to FIG. 2.

As described with reference to FIG. 2, a manufacturing system may perform compression molding to form an insulating layer 325 of a memory system. In some examples, the system 300-a, the system 300-b, and the system 300-c may illustrate the memory system at various steps of the compression molding performed by the manufacturing system. As shown in FIGS. 3A, 3B, and 3C, the memory system may include at least a substrate 310 and packages 315 coupled with the substrate 310 (e.g., a package 310-a, a package 315-b, and a package 315-c). Each package 315 may include one or more memory dies. Further, in some examples, each package 315 may include one or more wires 320 connecting different combinations of memory dies of a respective package 315 to the substrate 310.

FIGS. 3A and 3B may represent the memory system after a first set of operations performed by the manufacturing system during compression molding. As shown in FIG. 3A, the molding tool 305 may be positioned above the substrate 310 and the substrate 310 may be positioned such that the packages 315 coupled with the substrate 310 are between the substrate 310 and the molding tool 305. FIG. 3B may differ from FIG. 3A in that the substrate 310 may be positioned above the molding tool 305 and the substrate 310 may be positioned such that the packages 315 coupled with the substrate are between the substrate 310 and the molding tool 305.

In some examples, the first set of operations may include depositing (or forming) an EMC 330-a, an EMC 330-b, and an EMC 330-c in a cavity between the molding tool 305 and the substrate 310. In the FIG. 3A, the EMC 330-a, the EMC 330-b, and the EMC 330-c may be deposited on the substrate 310 and within the cavity. Alternatively, in FIG. 3B, the EMC 330-a, the EMC 330-b, and the EMC 330-c may be deposited on the molding tool 305 and within the cavity.

The EMC 330-a, the EMC 330-b, and the EMC 330-c may differ from one another. For example, the EMC-a, the EMC-b, and the EMC-c may include a different epoxy type, a different filler type, a different percentage of epoxy, or a different percentage of filler. Further, at least one property (e.g., a thermal property or an electrical property) may differ between the EMC 330-a, the EMC 330-b, and the EMC 330-c.

As shown in FIGS. 3A and 3B, different EMCs 330 may be deposited in different regions of the cavity. For example, the EMC 330-a may be deposited in a first region of the cavity, the EMC 330-b may be deposited in a second region of the cavity, and the EMC 330-c may be deposited in a third region of the cavity.

FIG. 3C may represent the memory system after the first set of operations and a second set of operation is performed by the manufacturing system during compression molding. The second set of operations may follow the first set of operations as described with reference to FIGS. 3A and 3B. In some examples, the second set of operation may include moving at least one of the substrate 310 or the molding tool 305 towards each other to form the insulating layer 325 that at least partially surrounds the packages 315.

As a result of the first set of operations and the second set of operations, the insulating layer 325 may include different EMCs 330. For example, one or more first portions of the insulating layer 325 may include the EMC 330-a, one or more second portions of the insulating layer 325 may include the EMC 330-b, and one or more third portions of the insulating layer 325 may include the EMC 330-c. In some examples, each of the one or more first portions may be positioned between respective pairs of package 315 and each of the one or more third portions may be positioned between respective pairs of first portions. Further, each of the one or more second portions may be positioned between a respective first portion and respective third portion. In some examples, each of the one or more second portions may be in contact with (e.g., at least partially surround) wires 320 of a respective package 315. Additionally, or alternatively, each of the one or more third portions may be in contact with a top surface of a respective package 315.

In some examples, a location of the EMC 330 within the insulating layer 325 may be based on the properties of the EMC 330. For example, the EMC 330-b may be used for the one or more third regions because the EMC 330-b may exhibit better electrical performance than other EMCs 330 (e.g., the EMC 330-a and the EMC 330-c) which may prevent crosstalk and improve shielding of the wires 320. As other examples, EMCs 330 that exhibit better heat dissipation than other EMCs 330 may be used in portions of the insulating layer 325 adjacent to or surrounding sensitive components of the memory system to pull heat away from the sensitive components. Additionally, or alternatively, EMCs 330 with similar coefficient of thermal expansion (CTE) as other materials of the memory system could be used in portions of the insulating layer 325 where warpage may be an issue. Additionally, or alternatively, EMCs 330 with better mechanical performance may be used in portions of the insulating layer 325 where laser marking is performed to protect the packages 315 and improve marking visibility. Additionally, or alternatively, EMCs 330 with a smaller filler type may be used in portions of the insulating layer 325 that have complex geometries to avoid gaps in material.

Although FIGS. 3A through 3C illustrate three EMC types (e.g., the EMC 330-a, the EMC 330-b, and the EMC 330-c) being used in the formation of the insulating layer 325, it may be understood that the insulating layer 325 may be formed using any quantity of EMC types (e.g., four types, five types, six types, etc.). Further, boundaries between each EMC 330 formed in the insulating layer 325 as illustrated in FIG. 3C are merely examples and it may be understood that boundaries of differing shapes and geometries are possible. In some cases, these formation techniques may create irregular boundaries between different types of EMC materials (as shown in FIG. 3C). In such examples, a boundary between two different types of EMC materials may characterized by series of irregularities that create a pattern of peaks and troughs. Such boundaries may form a rough and uneven boundary line between the two materials, with some twists and turns. Such boundaries may be different than boundaries formed between other types of materials that are formed using dry etching processes and/or planarization processes. Further, to improve aesthetics and marking visibility, the EMCs 330 included in the insulating layer may be dyed a same color (e.g., carbon black).

In some examples, boundaries between each EMC 330 formed in the insulating layer 325 may form a gradual transition from one EMC 330 to another EMC 330 in the insulating layer 325, in at least some portions of the boundaries. In other words, the compression molding process as described herein may create areas between different EMCs 330 that include a mixture of the different EMCs 330.

Tailoring the EMCs 330 to different portions of the insulating layer 325 may increase an overall performance of the memory system when compared to using a singular EMC 330 to form the insulating layer. Further, using multiple EMCs 330 to form the insulating layer 325 may decrease an overall manufacturing cost of the memory system.

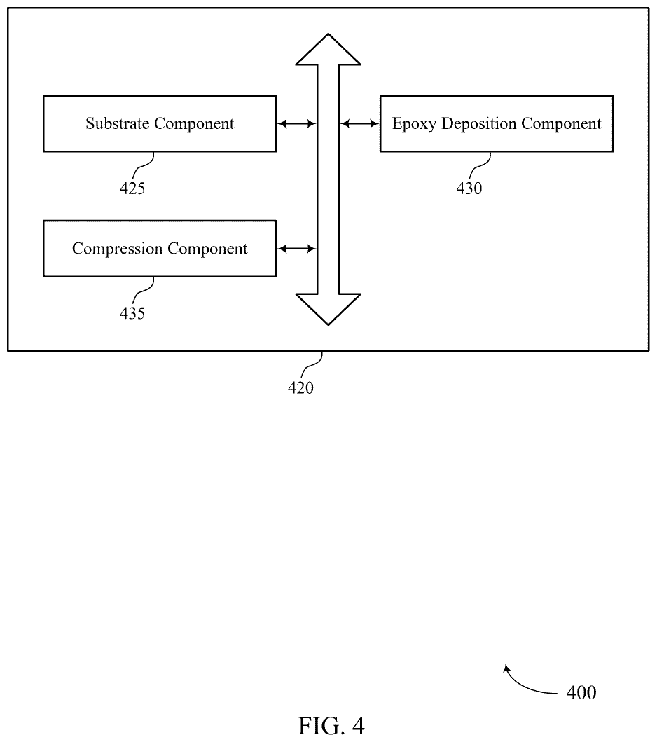

FIG. 4 shows a block diagram 400 of a manufacturing system 420 that supports multiple epoxy compounds for memory system manufacturing in accordance with examples as disclosed herein. The manufacturing system 420 may be an example of aspects of a manufacturing system as described with reference to FIGS. 1 through 3. The manufacturing system 420, or various components thereof, may be an example of means for performing various aspects of multiple epoxy compounds for memory system manufacturing as described herein. For example, the manufacturing system 420 may include a substrate component 425, an epoxy deposition component 430, a compression component 435, or any combination thereof. Each of these components, or components of subcomponents thereof (e.g., one or more processors, one or more memories), may communicate, directly or indirectly, with one another (e.g., via one or more buses).

The substrate component 425 may be configured as or otherwise support a means for forming a device including a substrate and one or more semiconductor packages. The epoxy deposition component 430 may be configured as or otherwise support a means for forming a first epoxy compound in a first region of a cavity between the substrate and a molding tool. In some examples, the epoxy deposition component 430 may be configured as or otherwise support a means for forming a second epoxy compound in a second region of the cavity, where at least one of an electrical property or a thermal property of the first epoxy compound is different than at least one of an electrical property or a thermal property of the second epoxy compound. The compression component 435 may be configured as or otherwise support a means for moving at least one of the device or the molding tool towards each other to form an insulating layer that at least partially surrounds the one or more semiconductor packages, the insulating layer including the first epoxy compound and the second epoxy compound.

In some examples, the epoxy deposition component 430 may be configured as or otherwise support a means for forming a third epoxy compound in a third region of the cavity, where at least one of an electrical property or a thermal property of the third epoxy compound is different than the at least one of the electrical property or the thermal property of the first epoxy compound and the at least one of the electrical property or the thermal property of the second epoxy compound, and where the insulating layer includes the first epoxy compound, the second epoxy compound, and the third epoxy compound.

In some examples, the insulating layer includes a plurality of regions, each region of the plurality of regions including a respective epoxy compound. In some examples, the plurality of regions include a plurality of first regions that are each positioned between a respective pair of semiconductor packages of the one or more semiconductor packages and a plurality of second regions that are each positioned between a respective pair of first regions. In some examples, the plurality of second regions include the first epoxy compound and the plurality of second regions includes the second epoxy compound.

In some examples, each of the plurality of first regions is in contact with at least one wire of a semiconductor package of the respective pair of semiconductor packages. In some examples, a dielectric strength of the first epoxy compound is higher than a dielectric strength of the second epoxy compound.

In some examples, each of the plurality of second regions is in contact with a top surface of a respective semiconductor package of the one or more semiconductor packages. In some examples, an electrical property of a respective epoxy compound includes conductance, resistance, resistivity, or dielectric strength of the respective epoxy compound. In some examples, a thermal property of a respective epoxy compound includes thermal expansion, heat capacity, thermal conductivity, or thermal stress of the respective epoxy compound. In some examples, one or more of a type of epoxy, a composition of a filler material, a size of the filler material, or a density of the filler material is different between the first epoxy compound and the second epoxy compound.

In some examples, the described functionality of the manufacturing system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the manufacturing system 420, or various components thereof, may be implemented at least in part by instructions (e.g., stored in memory, non-transitory computer-readable medium) executable by such at least one processor.

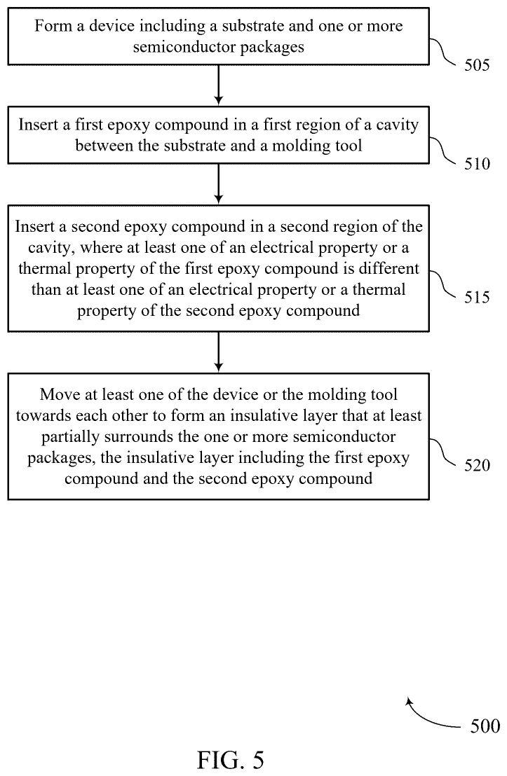

FIG. 5 shows a flowchart illustrating a method 500 that supports multiple epoxy compounds for memory system manufacturing in accordance with examples as disclosed herein. The operations of method 500 may be implemented by a manufacturing system or its components as described herein. For example, the operations of method 500 may be performed by a manufacturing system as described with reference to FIGS. 1 through 4. In some examples, a manufacturing system may execute a set of instructions to control the functional elements of the device to perform the described functions. Additionally, or alternatively, the manufacturing system may perform aspects of the described functions using special-purpose hardware.

At 505, the method may include forming a device including a substrate and one or more semiconductor packages. In some examples, aspects of the operations of 505 may be performed by a substrate component 425 as described with reference to FIG. 4.

At 510, the method may include inserting a first epoxy compound in a first region of a cavity between the substrate and a molding tool. In some examples, aspects of the operations of 510 may be performed by an epoxy deposition component 430 as described with reference to FIG. 4.

At 515, the method may include inserting a second epoxy compound in a second region of the cavity, where at least one of an electrical property or a thermal property of the first epoxy compound is different than at least one of an electrical property or a thermal property of the second epoxy compound. In some examples, aspects of the operations of 515 may be performed by an epoxy deposition component 430 as described with reference to FIG. 4.

At 520, the method may include moving at least one of the device or the molding tool towards each other to form an insulating layer that at least partially surrounds the one or more semiconductor packages, the insulating layer including the first epoxy compound and the second epoxy compound. In some examples, aspects of the operations of 520 may be performed by a compression component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a device including a substrate and one or more semiconductor packages; inserting a first epoxy compound in a first region of a cavity between the substrate and a molding tool; inserting a second epoxy compound in a second region of the cavity, where at least one of an electrical property or a thermal property of the first epoxy compound is different than at least one of an electrical property or a thermal property of the second epoxy compound; and moving at least one of the device or the molding tool towards each other to form an insulating layer that at least partially surrounds the one or more semiconductor packages, the insulating layer including the first epoxy compound and the second epoxy compound.

Aspect 2: The method, apparatus, or non-transitory computer-readable medium of aspect 1, further including operations, features, circuitry, logic, means, or instructions, or any combination thereof for inserting a third epoxy compound in a third region of the cavity, where at least one of an electrical property or a thermal property of the third epoxy compound is different than the at least one of the electrical property or the thermal property of the first epoxy compound and the at least one of the electrical property or the thermal property of the second epoxy compound, and where the insulating layer includes the first epoxy compound, the second epoxy compound, and the third epoxy compound.

Aspect 3: The method, apparatus, or non-transitory computer-readable medium of any of aspects 1 through 2, where the insulating layer includes a plurality of regions, each region of the plurality of regions including a respective epoxy compound.

Aspect 4: The method, apparatus, or non-transitory computer-readable medium of aspect 3, where the plurality of regions include a plurality of first regions that are each positioned between a respective pair of semiconductor packages of the one or more semiconductor packages and a plurality of second regions that are each positioned between a respective pair of first regions.

Aspect 5: The method, apparatus, or non-transitory computer-readable medium of aspect 4, where the plurality of second regions include the first epoxy compound and the plurality of second regions includes the second epoxy compound.

Aspect 6: The method, apparatus, or non-transitory computer-readable medium of aspect 5, where each of the plurality of first regions is in contact with at least one wire of a semiconductor package of the respective pair of semiconductor packages and a dielectric strength of the first epoxy compound is higher than a dielectric strength of the second epoxy compound.

Aspect 7: The method, apparatus, or non-transitory computer-readable medium of any of aspects 4 through 6, where each of the plurality of second regions is in contact with a top surface of a respective semiconductor package of the one or more semiconductor packages.

Aspect 8: The method, apparatus, or non-transitory computer-readable medium of any of aspects 1 through 7, where an electrical property of a respective epoxy compound includes conductance, resistance, resistivity, or dielectric strength of the respective epoxy compound.

Aspect 9: The method, apparatus, or non-transitory computer-readable medium of any of aspects 1 through 8, where a thermal property of a respective epoxy compound includes thermal expansion, heat capacity, thermal conductivity, or thermal stress of the respective epoxy compound.

Aspect 10: The method, apparatus, or non-transitory computer-readable medium of any of aspects 1 through 9, where one or more of a type of epoxy, a composition of a filler material, a size of the filler material, or a density of the filler material is different between the first epoxy compound and the second epoxy compound.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 11: An apparatus, including: a substrate; one or more semiconductor packages positioned over the substrate; and an insulating layer that at least partially surrounds the one or more semiconductor packages, where one or more first portions of the insulating layer include a first epoxy compound and one or more second portions of the insulating layer include a second epoxy compound, where at least one of an electrical property or a thermal property of the first epoxy compound is different than an electrical property or a thermal property of the second epoxy compound.

Aspect 12: The apparatus of aspect 11, where one or more third portions of the insulating layer include a third epoxy compound, at least one of an electrical property or a thermal property of the third epoxy compound is different than the at least one of the electrical property or the thermal property of the first epoxy compound and the at least one of the electrical property or the thermal property of the second epoxy compound.

Aspect 13: The apparatus of any of aspects 11 through 12, where each first portion of the one or more first portions is positioned between a respective pair of semiconductor packages of the one or more semiconductor packages and each second portion of the one or more second portions is positioned between a respective pair of first portions.

Aspect 14: The apparatus of aspect 13, where each second portion of the one or more second portions is in contact with a top surface of a respective semiconductor package of the one or more semiconductor packages.

Aspect 15: The apparatus of any of aspects 13 through 14, where each of the one or more first portions is in contact with at least one wire of a semiconductor package of the respective pair of semiconductor packages, and a dielectric strength of the first epoxy compound is higher than a dielectric strength of the second epoxy compound.

Aspect 16: The apparatus of any of aspects 11 through 15, where an electrical property of a respective epoxy compound includes conductance, resistance, resistivity, or dielectric strength of the respective epoxy compound.

Aspect 17: The apparatus of any of aspects 11 through 16, where a thermal property of a respective epoxy compound includes thermal expansion, heat capacity, thermal conductivity, or thermal stress of the respective epoxy compound.

Aspect 18: The apparatus of any of aspects 11 through 17, where one or more of a type of epoxy, a composition of a filler material, a size of the filler material, or a density of the filler material is different between the first epoxy compound and the second epoxy compound.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a substrate;
one or more semiconductor packages positioned over the substrate; and
an insulating layer that at least partially surrounds the one or more semiconductor packages, wherein one or more first portions of the insulating layer comprise a first epoxy compound, one or more second portions of the insulating layer comprise a second epoxy compound and one or more third portions of the insulating layer comprise a mixture of the first epoxy compound and the second epoxy compound, wherein at least one of an electrical property or a thermal property of the first epoxy compound is different than an electrical property or a thermal property of the second epoxy compound.

2. The apparatus of claim 1, wherein one or more fourth portions of the insulating layer comprise a third epoxy compound, and wherein at least one of an electrical property or a thermal property of the third epoxy compound is different than the at least one of the electrical property or the thermal property of the first epoxy compound and the at least one of the electrical property or the thermal property of the second epoxy compound.

3. The apparatus of claim 1, wherein each first portion of the one or more first portions is positioned between a respective pair of semiconductor packages of the one or more semiconductor packages and each second portion of the one or more second portions is positioned between a respective pair of first portions.

4. The apparatus of claim 3, wherein each second portion of the one or more second portions is in contact with a top surface of a respective semiconductor package of the one or more semiconductor packages.

5. The apparatus of claim 3, wherein each of the one or more first portions is in contact with at least one wire of a semiconductor package of the respective pair of semiconductor packages, and wherein a dielectric strength of the first epoxy compound is higher than a dielectric strength of the second epoxy compound.

6. The apparatus of claim 1, wherein an electrical property of a respective epoxy compound comprises conductance, resistance, resistivity, or dielectric strength of the respective epoxy compound.

7. The apparatus of claim 1, wherein a thermal property of a respective epoxy compound comprises thermal expansion, heat capacity, thermal conductivity, or thermal stress of the respective epoxy compound.

8. The apparatus of claim 1, wherein one or more of a type of epoxy, a composition of a filler material, a size of the filler material, or a density of the filler material is different between the first epoxy compound and the second epoxy compound.

9. A method of manufacturing an apparatus, comprising:
forming a device comprising a substrate and one or more semiconductor packages;
inserting a first epoxy compound in a first region of a cavity between the substrate and a molding tool;
inserting a second epoxy compound in a second region of the cavity, wherein at least one of an electrical property or a thermal property of the first epoxy compound is different than at least one of an electrical property or a thermal property of the second epoxy compound; and
moving at least one of the device or the molding tool towards each other to form an insulating layer that at least partially surrounds the one or more semiconductor packages, the insulating layer comprising the first epoxy compound, the second epoxy compound, and a mixture of the first epoxy compound and the second epoxy compound.

10. The method of claim 9, further comprising:
inserting a third epoxy compound in a third region of the cavity, wherein at least one of an electrical property or a thermal property of the third epoxy compound is different than the at least one of the electrical property or the thermal property of the first epoxy compound and the at least one of the electrical property or the thermal property of the second epoxy compound, and wherein the insulating layer comprises the first epoxy compound, the second epoxy compound, and the third epoxy compound.

11. The method of claim 9, wherein the insulating layer comprises a plurality of regions, each region of the plurality of regions comprising a respective epoxy compound.

12. The method of claim 11, wherein the plurality of regions comprise a plurality of first regions that are each positioned between a respective pair of semiconductor packages of the one or more semiconductor packages and a plurality of second regions that are each positioned between a respective pair of first regions.

13. The method of claim 12, wherein the plurality of second regions comprise the first epoxy compound and the plurality of second regions comprises the second epoxy compound.

14. The method of claim 13, wherein each of the plurality of first regions is in contact with at least one wire of a semiconductor package of the respective pair of semiconductor packages, and wherein a dielectric strength of the first epoxy compound is higher than a dielectric strength of the second epoxy compound.

15. The method of claim 12, wherein each of the plurality of second regions is in contact with a top surface of a respective semiconductor package of the one or more semiconductor packages.

16. The method of claim 9, wherein an electrical property of a respective epoxy compound comprises conductance, resistance, resistivity, or dielectric strength of the respective epoxy compound.

17. The method of claim 9, wherein a thermal property of a respective epoxy compound comprises thermal expansion, heat capacity, thermal conductivity, or thermal stress of the respective epoxy compound.

18. The method of claim 9, wherein one or more of a type of epoxy, a composition of a filler material, a size of the filler material, or a density of the filler material is different between the first epoxy compound and the second epoxy compound.

19. An apparatus, comprising:
one or more controllers configured to cause the apparatus to:
form a device comprising a substrate and one or more semiconductor packages;
insert a first epoxy compound in a first region of a cavity between the substrate and a molding tool;
insert a second epoxy compound in a second region of the cavity, wherein at least one of an electrical property or a thermal property of the first epoxy compound is different than at least one of an electrical property or a thermal property of the second epoxy compound; and
move at least one of the device or the molding tool towards each other to form an insulative layer that at least partially surrounds the one or more semiconductor packages, the insulative layer comprising the first epoxy compound, the second epoxy compound, and a mixture of the first epoxy compound and the second epoxy compound.

20. The apparatus of claim 19, wherein the one or more controllers are further configured to cause the apparatus to:
insert a third epoxy compound in a third region of the cavity, wherein at least one of an electrical property or a thermal property of the third epoxy compound is different than the at least one of the electrical property or the thermal property of the first epoxy compound and the at least one of the electrical property or the thermal property of the second epoxy compound, and wherein the insulative layer comprises the first epoxy compound, the second epoxy compound, and the third epoxy compound.

21. The apparatus of claim 19, wherein the insulative layer comprises a plurality of regions, each region of the plurality of regions comprising a respective epoxy compound.

22. The apparatus of claim 21, wherein the plurality of regions comprise a plurality of first regions that are each positioned between a respective pair of semiconductor packages of the one or more semiconductor packages and a plurality of second regions that are each positioned between a respective pair of first regions.
